(19) United States
(12) Patent Application Publication
(10) Pub. No.: US 2026/0110760 A1
(43) Pub. Date: Apr. 23, 2026

(54) Magnetic Resonance Device with Additional Magnetic Gradient Field Acting on a Paramagnetic Contrast Agent

(71) Applicant: Siemens Healthineers AG, Forchheim (DE)

(72) Inventor: Stefan Popescu, Erlangen (DE)

(73) Assignee: Siemens Healthineers AG, Forchheim (DE)

(21) Appl. No.: 19/361,090

(22) Filed: Oct. 17, 2025

(30) Foreign Application Priority Data
Oct. 18, 2024 (DE) 10 2024 210 092.7

(51) Int. Cl. G01R 33/28; G01R 33/50; G01R 33/563

(52) U.S. Cl. CPC G01R 33/282; G01R 33/50; G01R 33/56341; G01R 33/56366

(57) ABSTRACT

A computer-implemented method for operating a magnetic resonance device, the method including: acquiring, as part of an examination process, magnetic resonance data describing diffusion and/or perfusion in a target area of a subject under examination in which an exogenous paramagnetic contrast agent is present, using a magnetic resonance sequence; and prior to at least one acquisition period in which magnetic resonance data of a dynamic data set is acquired using the magnetic resonance sequence, outputting an additional magnetic gradient field to generate a magnetic movement force that acts on the contrast agent to introduce kinetic energy into the target area, wherein the additional magnetic gradient field is output separately from pulses of the magnetic resonance sequence.

### TECHNICAL FIELD

The disclosure relates to a computer-implemented method for operating a magnetic resonance device, wherein, in the course of an examination procedure, a magnetic resonance sequence is used to acquire magnetic resonance data describing the diffusion and/or perfusion in a target area of a subject under examination, said target area containing an exogenous paramagnetic contrast agent. The disclosure also relates to a magnetic resonance device, a computer program, and an electronically readable data carrier.

### BACKGROUND

Magnetic resonance imaging is an established tool in medical technology, particularly in the context of diagnosis and/or monitoring and assessment of the success of interventions or other therapeutic measures. A variety of imaging techniques have been developed to examine different properties of materials and, in particular, of tissues. On this basis, magnetic resonance imaging is also employed in the diagnosis and staging of various forms of cancer or other related diseases. For example, magnetic resonance imaging can be used to detect and stage the most common cancers in men and women, namely prostate cancer and breast cancer, respectively. Early and accurate diagnosis of cancer is essential for appropriate and successful treatment.

The use of magnetic resonance imaging for the detection and staging of malignant tumors exhibits high sensitivity but low specificity. Magnetic resonance-based diagnostic methods produce many false-positive findings, which means that further tests and examinations are necessary. For example, the diagnosis of suspicious lesions as cancer can be confirmed by a biopsy of the affected tissue. Once the initial diagnosis has been made, further tests are performed to determine whether the cancer has spread beyond the original organ and which treatment options are most likely to be successful. These further steps are extremely time-consuming and taxing for patients with a false-positive magnetic resonance finding, as they expose patients to increased stress and dissatisfaction and also place a significant cost burden on the healthcare system. Consequently, there is controversy regarding the use of magnetic resonance imaging for screening for prostate cancer and breast cancer.

In order to improve the reliability of magnetic resonance examinations more generally, it is known to determine a plurality of parameters of the tissue in a single examination procedure with a magnetic resonance device. Such examination procedures are referred to as multiparametric magnetic resonance imaging. In multiparametric magnetic resonance imaging, a plurality of magnetic resonance sequences are combined in an imaging protocol in order to provide comprehensive information about the structure, function, and composition of tissues in the human body. By combining magnetic resonance data from different magnetic resonance contrasts, such as T1-weighted, T2-weighted, diffusion-weighted, and dynamic contrast-enhanced (DCE) imaging, multiparametric magnetic resonance imaging allows a detailed assessment of various physiological parameters, such as cellularity, vascularity, and tissue mobility. The detection, characterization, and staging of various diseases, especially cancer, is one of the main fields of application for multiparametric magnetic resonance measurements.

In particular, multiparametric MRI (multiparametric magnetic resonance measurement) is the imaging modality of choice for local staging of prostate cancer (PCa) and incrementally improves the assessment of pelvic lymph node disease and bone involvement. However, there are studies showing that multiparametric MRI is not reliable enough to be used as the sole means of staging prior to prostatectomy. The interpretation must take place while taking the risk of the individual patient into account.

Multiparametric magnetic resonance measurement is also a highly sensitive and specific imaging modality for breast cancer detection and staging, but it too has limitations. The routine use of magnetic resonance imaging in preoperative staging for breast cancer is a subject of debate, as it has not been possible to demonstrate any improvement in patient outcomes, including mortality and recurrence. Image-guided biopsy is still required to confirm multifocal, multicentric, or contralateral cancers when additional suspicious findings are detected by magnetic resonance imaging in a patient with breast cancer.

The pathophysiological basis for the contrasts that allow magnetic resonance imaging to distinguish between pathological and non-pathological tissue is based on the observation that malignant and aggressive neoplasms exhibit higher degrees of neovascularity, as blood vessels supply nutrients to the rapidly proliferating cells. Consequently, the proportion of tissue occupied by blood vessels is increased. The blood vessels in tumors have an enlarged surface area and are inherently less dense. Consequently, their permeability per unit surface area is increased, allowing contrast agents to pass more quickly from the blood vessels into the interstitial space, i.e., the space between cells that is filled with interstitial fluid. In addition, malignant tumors often have necrotic regions, so that the proportion of extracellular space is also increased compared to more benign tumors.

These specific properties of malignant tissue can be detected by two known magnetic resonance contrast mechanisms, namely dynamic contrast-enhanced magnetic resonance imaging (DCE-MRI) and diffusion-weighted imaging (DWI).

In DCE-MRI, an exogenous contrast agent is administered to the patient prior to the actual magnetic resonance examination, for example, by intravenous injection or orally. Examples of exogenous contrast agents for magnetic resonance imaging include gadolinium-, iron-, and manganese-based contrast agents, with gadolinium (Gd)-based contrast agents (GBCA) being the most commonly used. Immediately after injection, the contrast agent circulates with the blood flow into the target area. The relatively small molecular size of the contrast agent allows it to pass through the vascular endothelium into the interstitial space of tissues by passive diffusion due to a concentration gradient. The German physicist Adolf Fick modeled diffusion as the movement of particles from a region of higher concentration to a region of lower concentration, being proportional to the concentration gradient. The contrast agent does not enter cells. The most commonly used evaluation method for DCE measurements is simple visual assessment of contrast enhancement at different time points. Both the pattern of contrast agent uptake and the estimated entry/exit rates (“wash-in”/“wash-out”) of a lesion provide clinical information about its nature.

In DWI, molecular diffusion in biological tissues is measured. In this case, the contrast mechanism is provided by the passive microscopic mobility of water molecules in different tissues. The water molecules interact with many different obstacles as they diffuse within organs. In this way, diffusion-weighted imaging can provide insights into the microscopic details of different tissues. For example, tissue structures such as cell membranes can impede the diffusion motion of water molecules. It follows that tissues with a high cell density or cellularity can be distinguished from tissues with less densely arranged cells or from pure fluid.

Both DCE imaging and diffusion-weighted imaging are usually included in acquisition protocols for multiparametric magnetic resonance measurements. Although sensitivity and specificity for cancer detection and staging can also be increased in this way, it results in longer acquisition times and higher costs.

### SUMMARY

An object of the disclosure is to specify a means for improving perfusion and diffusion measurements in magnetic resonance imaging, particularly with respect to sensitivity and specificity.

To achieve this object, a computer-implemented method, a magnetic resonance device, a computer program, and an electronically readable data carrier as claimed in the independent claims are provided according to the disclosure. Advantageous developments will emerge from the subclaims.

In a method of the type mentioned in the introduction, the disclosure provides that, prior to at least one acquisition period in which magnetic resonance data of a dynamic data set is acquired by means of the magnetic resonance sequence, an additional magnetic gradient field is output to generate a magnetic movement force acting on the contrast agent in order to introduce kinetic energy into the target area separately from the pulses of the magnetic resonance sequence.

It should be noted that, in general, an acquisition protocol can be used that employs a plurality of magnetic resonance sequences. At least one of the at least one magnetic resonance sequences employed is used to acquire magnetic resonance data describing the diffusion and/or perfusion of water and/or contrast agent. Specifically, therefore, the magnetic resonance sequence is used for dynamic contrast-enhanced imaging (DCE imaging) and/or diffusion-weighted imaging (DWI), as will be explained in more detail below with reference to examples.

In the context of the present disclosure, it has been recognized that a significant limitation of known DCE and DWI techniques is that they are based on the passive perfusion or diffusion of the respective contrast-providing medium (contrast agent or water). In DCE magnetic resonance imaging, the contrast dynamics are driven solely by the concentration gradient of the contrast agent distribution in the tissue. Once the concentration gradient disappears at the end of the contrast agent uptake phase (“arterial first pass”), no significant enhancement or dynamics are available for deriving additional information about the tissue structure. Correspondingly, in DWI, the contrast depends solely on the passive microscopic mobility of water molecules in different tissues. In order to obtain a sufficiently high signal-to-noise ratio in the diffusion images, known DWI methods use very long diffusion encoding times and/or strong diffusion encoding gradients. Therefore, instead of or in addition to the known passive approaches, it is proposed, according to the disclosure, to also actively drive the perfusion or diffusion.

To this end, the magnetic properties of the most commonly used exogenous contrast agents are utilized to impart motion to them and thereby introduce kinetic energy. In particular, use is made of the fact that most contrast agents used, especially the frequently employed gadolinium-based contrast agents, are paramagnetic, which likewise applies to their molecules. Paramagnetic molecules of a gadolinium-based contrast agent generate a magnetic moment when placed in a static magnetic field, in this case, the main magnetic field (B0 field) of the magnetic resonance device. This also applies to iron-based or manganese-based contrast agents and their molecules, as well as to superparamagnetic iron oxide (SPIO) nanoparticles, which are likewise known for use as magnetic resonance contrast agents. According to the disclosure, the paramagnetic contrast agent molecules are set in motion by an externally generated magnetic field, namely the additional gradient field, separately from the magnetic resonance sequences themselves, so that diffusion and/or perfusion can be actively driven.

It should be noted at this point that the introduction of the contrast agent is not part of the method according to the disclosure, but that the method commences when the contrast agent is already within the subject under examination, in particular the patient, specifically in the target area. Contrast agents in magnetic resonance imaging are not measured directly but influence the relaxation times of spins of protons bound in water. Due at the very least to the occurrence of collisions with water molecules and/or the occurrence of locally higher concentrations of contrast agent, the movement of contrast agent molecules results in measurable contrast differences and, in particular, provides improvements, as will be explained in more detail below.

In this way, effects to be measured, such as diffusion and perfusion, can be deliberately induced or enhanced, resulting in increased sensitivity and specificity, particularly with regard to cancer detection and staging. In addition, particularly with respect to diffusion imaging, this allows a significant reduction in scan times or opens up a new imaging approach for diffusion imaging that can supersede prior approaches, as will be explained in more detail below.

According to the disclosure, it is preferred to output the additional gradient field in a dedicated time period (movement time period) immediately prior to the acquisition period, separated in time from the pulses of the magnetic resonance sequence, in order to have as little effect as possible on the actual measurement using the magnetic resonance sequence. In principle, however, exemplary aspects are also conceivable in which the additional gradient field is output in parallel with at least some of the pulses of the magnetic resonance sequence. In the preferred first case, movement time periods (“drive”) and acquisition periods (“scan”) may alternate at least temporarily, so that, for example, a sequence such as “scan”, “drive”, “scan again” can result, and a comparison of magnetic resonance data from a reference data set prior to the introduction of kinetic energy and the dynamic data set after the introduction of kinetic energy can be performed to assess the effect of the additional gradient field.

The physical principles for the introduction of kinetic energy, i.e., deliberate movement of molecules of the paramagnetic contrast agent, will be briefly outlined again below. When molecules of the paramagnetic contrast agent are placed in the strong and homogeneous static main magnetic field B₀ (B0 field) of the magnetic resonance device, they form internal magnetic fields, thereby creating an induced molecular magnetic moment M. The external static magnetic field B₀ exerts a torque T on this magnetic moment M in order to align it in the direction of the external magnetic field B₀, as described by the following vector equation:

$$T = V ( M \times {B}_{0} ) .$$

Here, as in the following, vector quantities are indicated in bold type and scalar quantities in normal type. V denotes the volume of the paramagnetic molecule or particle.

If strong magnetic field gradients BG_{x,y,z} are applied across the image volume, in particular at least the target area, these exert a magnetic force F on these molecular magnetic moments M, resulting in a moving action that pushes the contrast agent molecules along the well-defined direction of the force F, as described by the following vector equations:

$$F = V ( M \cdot ∇ ) {B}_{g} where$$

$${B}_{g} = {B}_{0} + B {G}_{x} + B {G}_{y} + B {G}_{z} = B {G}_{x} i + B {G}_{y} j + ( {B}_{0} + B {G}_{z} ) k ,$$

where (i, j, k) are the unit vectors along the X, Y, and Z axes, respectively. The Z axis is usually the direction of the B₀ field. Since the small magnetic moments M of the contrast agent molecules are mainly oriented along the direction of the main magnetic field, i.e., the Z direction, it follows that

$$M = mk and F = V m \frac{\partial {B}_{g}}{\partial z} .$$

In a particularly preferred development of the present disclosure, it may be provided that the additional gradient field is output as a gradient field generated by a gradient coil arrangement of the magnetic resonance device using additional gradient pulses. This means that additional gradient pulses are output by means of the gradient coil arrangement, thereby generating the additional gradient field. As a result, no additional magnetic field generating arrangement is necessary. The same hardware that has hitherto been used (and will also continue to be used within the scope of the present disclosure) to generate the gradient fields for spatial encoding and acquisition of the magnetic resonance signals can therefore be used to generate the additional gradient field. The gradient coil array may, in particular, comprise gradient coils for the X, Y, and Z axes.

The real vector field distribution of the magnetic resonance gradient fields is used to derive, specifically, the magnetic movement force that acts on the contrast agent molecules of the paramagnetic contrast agent and is generated by operation of the conventional gradient coils of the magnetic resonance device. These gradient fields also include vector field components that are not parallel but orthogonal to the direction of the main magnetic field. These orthogonal components are known in the literature as “concomitant terms” or Maxwell terms. They are unavoidable because they are a consequence of the laws of physics (described by the Maxwell equations), which require that the vector magnetic field should have zero divergence and negligible rotation within the imaging volume. Since the magnitudes of the Maxwell terms are comparable to the magnitude of the Z-direction gradients used for signal encoding in magnetic resonance imaging, they cannot be neglected when determining the force F acting on the contrast agent molecules. If the first-order approximations of the Maxwell terms, as described, for example, in US 2023/0333190 A1, are used, the following applies:

$${B}_{g} ( x , y , z ) = ( z \cdot {G}_{x} - x \frac{{G}_{z}}{2} ) i + ( z \cdot {G}_{y} - y \frac{{G}_{z}}{2} ) j + ( {B}_{0} + x \cdot {G}_{x} + y \cdot {G}_{y} + z \cdot {G}_{z} ) k ,$$

where Gₓ, G_{y}, and G_{z} describe the strengths of the applied gradients along the Cartesian axes. These variables may take positive or negative values, for example, to reverse the direction of the gradient fields. The resulting final expression for the movement force F is thus obtained:

$$F ( x , y , z ) = V m ( {G}_{x} i + {G}_{y} j + {G}_{z} k ) .$$

This yields two important conclusions for an expert in magnetic resonance imaging.

First, the Maxwell term of the Gₓ gradient pushes the contrast agent molecules along the X axis. The Maxwell term of the G_{y} gradient pushes the contrast agent molecules along the Y axis. The term of the G_{z} gradient (which is useful for encoding the magnetic resonance signals) pushes the contrast agent molecules along the Z axis.

Second, in the case of linear gradients, the movement force acting on the contrast agent molecules is the same at every location within the imaging volume. It depends solely on the strength, direction, and polarity of the applied magnetic gradient fields. By combining suitable gradient strengths, directions, and polarities, it is therefore possible to deliberately generate a movement force that moves the contrast agent molecules in a predefined spatial direction.

A particularly preferred development of the present disclosure provides that the output of the additional gradient field and the subsequent measurement take place in a window of opportunity of the examination process in which there is an at least substantially constant contrast agent concentration in a subvolume of interest, bounded by at least one anatomical structure, in particular an interstitial space, of the target area. Special timing is thus proposed in order to extend the availability and usability of contrast agent within the tissue beyond the capabilities of known methods. In the prior art, various typical contrast agent enhancement or concentration curves are known, which can also be used in the analysis for the detection, classification, and staging of tumors in a variety of organs, including the liver, the female breast, and the male prostate. Tissues that exhibit a first type of contrast agent concentration curve in interstitial spaces, i.e., interstitial-fluid-filled spaces between cells, said curve indicating a slow, progressive uptake of contrast agent over time, are more likely to be benign, while those of a third type with rapid uptake of contrast agent followed by slower wash-out are more likely to be malignant. Tissues or lesions with an intermediate contrast agent curve culminating in a plateau (second type of curve) are also known. All of these curves have in common that contrast agent is initially taken up into the interstitial space due to a concentration gradient. This is a passive process. Once a maximum is reached, particularly for the second and third types of curve, the progression is far less dynamic, as the concentration gradient gradually decreases. However, the tissues that exhibit a curve of the second or third type are the most relevant subvolumes in the target area.

According to the disclosure, it is now proposed to make use of the previously “useless” time periods of relatively constant contrast agent concentration in the interstitial spaces (or other relevant subvolumes), said time periods exhibiting little dynamic behavior, by significantly increasing the amount of information that can be collected overall about the tissue by deliberately introducing kinetic energy. This exploits the fact that a significant amount of contrast agent is still present within the tissue, specifically in the subvolumes. Such a window of opportunity, therefore, provides a way of actively bringing about a change under relatively constant, predictable conditions, and of measuring its effect. Thus, not only can a period of time that was previously unused be utilized, but additional information can also be collected, resulting in a significant improvement in sensitivity and specificity, particularly in tissues exhibiting a type-2 contrast agent concentration curve. Tissues with a type-2 curve are those that previously could not be clearly associated with malignant or benign behavior and can lead to false-positive or false-negative findings. If the window of opportunity is purposefully exploited to gather additional information in the form of magnetic resonance data from the dynamic data set, the number of erroneous conclusions can be significantly reduced.

Specifically, it can therefore be provided that the window of opportunity comprises a period after a contrast agent inflow phase in which the contrast agent accumulates in the subvolume and/or that the presence of the window of opportunity is ascertained from a contrast agent time curve in the at least one voxel of the subvolume, said voxel being obtained from a previously acquired portion of the magnetic resonance data. For example, in a DCE measurement, as already described, the contrast agent concentration is usually measured at least indirectly by the contrast enhancement occurring over time, so that, for example, a curve which can typically be of type-1, type-2, or type-3 is obtained for each voxel. In a trigger unit of a control device of the magnetic resonance device, the contrast agent curve can, for example, be evaluated against an opportunity condition to determine when the window of opportunity has been reached. For example, the opportunity condition can check whether a maximum contrast agent concentration or contrast agent enhancement has been reached or exceeded, and/or whether a change in the contrast agent concentration (for example, its temporal gradient) is below a threshold value when a contrast agent concentration that exceeds a minimum concentration is present. Once the window of opportunity has been reached, kinetic energy can be introduced into the contrast agent present in the subvolume, for example, contrast agent located in interstitial spaces, by outputting the additional gradient field, and a measurement using the magnetic resonance sequence can then be performed. Thus, the temporary formation of contrast agent reservoirs in the subvolumes is exploited in order to make them the subject of additional measurements and information gathering.

An expedient development of the present disclosure, which can be used generally, provides that the magnetic resonance data of the dynamic data set is acquired at least partially using a simultaneous multi-slice technique, in particular in at least three slices. Simultaneous multi-slice (SMS) techniques that are generally known in the prior art make it possible to measure in a plurality of slices simultaneously, in particular slices arranged parallel to one another, so that the effect of the additional gradient field can expediently be verified at different locations, for example for different subvolumes, and in particular also compared. This takes place under identical conditions, in particular with regard to the existing gradient fields (also used in the magnetic resonance sequence), which further promotes comparability. In addition, acquisition time is saved since data acquisition can be performed simultaneously for a plurality of slices or a plurality of subvolumes of interest.

In a particularly advantageous aspect of the present disclosure, it is provided that the additional gradient field causes the molecules of the paramagnetic contrast agent to move in a predefined direction. In particular, this predefined direction is fixed for the immediately subsequent acquisition of at least one partial data set of the dynamic data set. In other words, this means that, in each movement time period immediately preceding an acquisition period, the same predetermined direction is used throughout. For advantageous exemplary aspects of this kind, it is therefore proposed to introduce kinetic energy into the contrast agent in a directed manner. This makes it possible to selectively examine the predefined directions in which the force acts and to draw direction-related conclusions about diffusion and perfusion. The relationships and findings derived above regarding the movement force, its direction, and its strength can be used to determine the appropriate additional gradient field and, thus, in particular, appropriate additional gradient pulses. Outside the magnetic resonance sequence, in particular prior to a scan/acquisition period or between scans/acquisition periods, the additional gradient field is therefore generated in order to move or push the contrast agent molecules in a desired, predefined spatial direction. The subsequent acquisition period generates magnetic resonance data or images that show the result of the displacement of the contrast agent and thus provide new information about the local tissue structure and/or the tissue permeability that prevents the free flow of the contrast agent.

When using the simultaneous multi-slice technique, the latter can be employed in a specific manner so that as much information as possible is obtained, including with regard to the known, predefined direction. For example, and as a matter of preference, the plurality of slices of the simultaneous multi-slice technique can extend perpendicularly to the predefined direction and in parallel with each other.

The magnetic resonance data of the dynamic data set can be acquired specifically as a contrast-enhanced measurement with a T1 contrast and/or with a T2* contrast.

If a magnetic resonance frequency with T1 weighting is used for acquisition of the dynamic data set, the contrast enhancement preferably results from a shortening of the T1 relaxation time due to a local accumulation of contrast agent, so that areas of hyperintensity appear in T1-weighted images. In particular, by using the additional gradient field, a stronger T1 contrast can be achieved compared to conventional methods. This is due to a memory effect associated with the tumbling rate of water molecules in the tissue fluids. During the movement time period, i.e., when the additional gradient field is applied, the displacement of the contrast agent molecules increases the probability of collision between the contrast agent molecules and the signal-generating water molecules. In principle, the contrast agent molecules alter the tumbling rate of the water molecules such that the T1 relaxation time is shortened. This effect is amplified by the higher kinetic activity of the contrast agent molecules, which also results in a slight increase in local temperature. Due to a thermo-mechanical memory effect, the higher kinetic molecular interaction persists even during the acquisition period, i.e., until the magnetic resonance data is acquired with the magnetic resonance sequences, until all the kinetic energy that was introduced into the tissue has dissipated. These latent thermo-mechanical interactions result in a shorter T1 relaxation time for the magnetic resonance data acquired with a fast readout sequence after the movement time period.

A comparable effect also occurs in T2*-weighted measurements. In tissues with restricted perfusion, especially restricted permeability, in the specified direction, a higher local concentration of contrast agent molecules occurs. This, in turn, increases the signal loss in T2*-weighted magnetic resonance sequences due to the contrast-agent-induced □B₀ susceptibility, which is given by

$$\frac{1}{{T}_{2}^{*}} = \frac{1}{{T}_{2}} + γ Δ {B}_{0} .$$

A higher contrast compared to conventional perfusion measurements also occurs with respect to T2* weighting. In this case, the memory effect is associated with the Brownian motion of water molecules within the tissue fluids. During the movement time period, the movement of the contrast agent molecules increases the probability of collision between the contrast agent molecules and the signal-generating water molecules. This increases the average magnitude of the Brownian motion, together with a slight increase in local temperature. Due to a thermo-mechanical memory effect, the stronger Brownian motion persists into the acquisition period until the kinetic energy introduced into the tissue has dissipated. This latent thermo-mechanical energy accelerates spin dephasing through dipole-dipole interactions, which in turn results in shorter T2 and T2* relaxation times for the magnetic resonance data acquired with a fast readout sequence after the movement time period.

In order to exploit predefined directions, it may be provided that different partial data sets of the dynamic data set are acquired in acquisition periods following the output of different additional gradient fields that cause movement in different predefined directions and are evaluated with regard to isotropy of perfusion and/or diffusion. Biological tissues are generally highly anisotropic. This means that their perfusion rates differ depending on direction. However, in malignant tissue, isotropy occurs due to the compaction effect described earlier and serves as a useful indicator for identifying the tissue as malignantly altered or tumorous. For example, perfusion of the contrast agent may be equally restricted in all directions, resulting in increases in contrast agent concentration at the respective barriers. In general, it can be said that clinical information about the isotropy of diffusion and/or perfusion is specific to healthy or abnormal tissue and therefore represents a useful adjunct to diagnostic evaluation.

It is therefore proposed to acquire partial data sets of the dynamic data set for different predefined directions, preferably at least partially orthogonal to one another, and to compare the effects of the corresponding additional gradient fields with one another so that information or, more specifically, a measure of the isotropy or anisotropy in the tissue, in particular with respect to at least one subvolume, can be derived. It is particularly advantageous if a plurality of sequences of a first acquisition period (without a preceding additional gradient field), a movement time period, and a subsequent second acquisition period (for measuring the effects of the additional gradient field of the movement time period), which can be understood in the short notation introduced above as “scan”, “drive”, “scan again”, are used for different, predefined directions, in particular at least partially orthogonal to one another, in order to acquire the partial data sets with associated reference magnetic resonance data of the reference data sets. By considering these different predefined directions and their measurement results together, it is possible to draw conclusions about the isotropy of diffusion and/or perfusion, in particular with regard to the presence of perfusion obstacles for the contrast agent that result in accumulations, as already described above specifically for T1 and T2* measurements.

In principle, it is also conceivable within the scope of the present disclosure to carry out the measurement in only one predefined direction and, in particular, after comparison with the magnetic resonance data acquired in the first acquisition period without an additional gradient field, to perform a comparison against statistically determined reference values. For example, the reference values may describe a “normal” range and a “pathological” range or may be subdivided still further.

In another advantageous aspect, using predefined directions that are fixed for partial data sets, it may be provided that, in order to measure a perfusion tensor in a measurement sequence, partial data sets of the dynamic data set are acquired and evaluated for different predefined directions of movement introduced by the additional gradient field. Healthy biological tissue is, at the very least, markedly anisotropic, which means that its perfusion rates differ in different directions. A number of prior art approaches ignore this complexity and describe perfusion using a single average value. In this aspect of the present disclosure, it is proposed to also detect and quantify anisotropic perfusion. In this way, valuable clinical information is obtained about existing tissue heterogeneity, which is often specific to healthy tissue, or about abnormal tissue homogeneity, which is an indicator of malignant changes.

By repeatedly applying additional gradient fields, in particular by performing the “scan”, “drive”, “scan again” sequence described above for different predefined directions of movement, it is possible to estimate direction-related tissue permeability for contrast agent molecules and thus reconstruct a complete tensor of tissue permeability as a perfusion tensor. The magnetic field gradient provided by the additional gradient field can be understood as a type of perfusion control gradient.

A tensor is a mathematical tool for representing the relationship between two vectors. For example, if a force is exerted on an object, movement may result. If the movement relates to a single direction, the transformation can be described by a vector or a rank-1 tensor. In dense tissues, the driven perfusion results in movement of contrast agent molecules along trajectories that extend in different directions over time, resulting in complex projections onto the Cartesian axes X, Y, and Z. If an internal anisotropic structure of the tissue is present that restricts the free movement of the contrast agent molecules, this is reflected in a specific perfusion pattern. The relationship between the movement force of the perfusion and the resulting perfusion pattern within the tissue can be described by a perfusion tensor. In the general approach, the controlled molecular displacements are described by nine components of the perfusion tensor, wherein each component is assigned to a pair of axes XX, YY, ZZ, XY, YX, XZ, ZX, YZ, ZY. The symmetric matrix of these components is the perfusion tensor:

$$\overline{P} = \vert \begin{matrix}{P}_{x x} & {P}_{x y} & {P}_{x z} \\ {P}_{x y} & {P}_{y y} & {P}_{y z} \\ {P}_{x z} & {P}_{y z} & {P}_{zz}\end{matrix} \vert .$$

The three diagonal elements (Pₓₓ, P_{yy}, P_{zz}) represent perfusion coefficients along the Cartesian axes X, Y, Z. The six off-diagonal elements represent the correlation of movements between each pair of axes. In the special case of perfect isotropic perfusion, all components except the diagonal elements are zero. The diagonal elements all correspond to the single perfusion coefficient P for isotropic tissue. For anisotropic perfusion, the diagonal elements are not equal, and the off-diagonal elements are not zero.

If in-slice measurements are performed, perfusion in one direction, namely the slice direction in which the slices follow one another, can be observed by observing the exchange of contrast agent between the slices. If the perfusion tensor of each voxel is now to be determined from a plurality of different perfusion-weighted measurements, i.e. partial data sets of the dynamic data set, it may be provided, for example, to acquire six partial data sets, wherein a different combination of the two directions involved (predefined direction of the movement force and slice direction) is used for each partial data set. For example, the movement force can be applied in the X direction, with a plurality of slices adjacent in the Z direction being acquired by simultaneous multi-slice imaging. Well-known mathematical relationships, such as those known from diffusion imaging (DWI), specifically diffusion tensor imaging (DTI) in this case, can be used to determine the perfusion tensor. For example, linear regression can be used to determine the diffusion tensor from the signal loss value in tissue voxels due to passive diffusion of water molecules. Accordingly, it is conceivable to determine the perfusion tensor based on active perfusion of contrast agent molecules. Similarly to such approaches, the trace of the perfusion tensor, i.e., an “average permeability” of the tissue, can already be determined by applying a movement force in only three predefined directions (in particular X, Y, and Z). In a three-dimensional measurement, a plurality of direction combinations can also be inferred and evaluated from a single measurement process.

As already explained above, this approach allows important information about anatomical target structures to be obtained with the aim of improving the classification and staging of tumors. For example, it is known that benign prostate tissue is highly heterogeneous in the transition zone. Prostate cancer destroys this natural heterogeneity, with the malignant tissue becoming highly homogeneous and thus altering the perfusion behavior, which can, in particular, be very effectively detected by determining a perfusion tensor.

In an alternative, advantageous aspect of the disclosure, it may be provided that, for diffusion-weighted acquisition of the dynamic data set, the additional gradient field is output to increase the diffusion movement. With regard to diffusion-weighted measurements, it is therefore proposed to utilize the presence of contrast agent in order to specifically enhance the existing diffusion. For example, if a multiparametric magnetic resonance measurement is performed anyway, contrast agent may already be present which can expediently be used to actively enhance passive diffusion through application of the movement force. In order to achieve isotropic enhancement of diffusion, it may be provided that an additional gradient field, varying over time with respect to the direction of the movement force, is used in particular such that the kinetic energy is introduced isotropically, for example, by means of mutually compensating directed components. Actively enhanced diffusion enables more accurate measurement. This can be easily achieved by providing contrast agent and selectively moving it by means of additional gradient fields.

It may be particularly advantageous for the dynamic data set to be acquired as part of a multiparametric magnetic resonance measurement, wherein the dynamic data set is used to determine at least one parameter of the plurality of parameters to be determined in the multiparametric measurement. Through active stimulation of perfusion and/or diffusion, additional information can be obtained, which, particularly in conjunction with information from multiparametric magnetic resonance measurements already known in the prior art, as mentioned above, allows a significant improvement in detection of malignant changes, classification of tissues, and staging, in particular of cancers.

In addition to the method, the present disclosure also relates to a magnetic resonance device, having a control device designed to carry out the method according to the disclosure. All aspects relating to the method according to the disclosure can be applied analogously to the magnetic resonance device according to the disclosure and vice versa, meaning that the advantages already mentioned can also be achieved with the magnetic resonance device.

The magnetic resonance device may in particular comprise a main magnet unit having a patient bore, in particular a cylindrical patient bore, into which a subject under examination can be moved by means of a patient table. The magnetic resonance device further comprises a gradient coil arrangement with gradient coils for generating gradient fields in the course of the magnetic resonance measurement and a radiofrequency coil arrangement for outputting radiofrequency pulses and receiving magnetic resonance signals. The control device has at least one processor and at least one memory. Functional units can be realized in hardware and/or software to carry out steps of the method according to the disclosure. As is known in principle, the control device has a sequence unit designed to control the other magnetic resonance device components for acquiring magnetic resonance data in accordance with an acquisition protocol comprising at least one magnetic resonance sequence. According to the disclosure, the sequence unit is further designed to control at least one further component of the magnetic resonance device, in particular the gradient coil arrangement for outputting corresponding additional gradient pulses, prior to at least one acquisition period in which magnetic resonance data of a dynamic data set is acquired by means of at least one of the at least one magnetic resonance sequence, in order to output an additional magnetic gradient field for generating a magnetic movement force to introduce kinetic energy into the target area separately from pulses of the at least one magnetic resonance sequence, thereby generating such a field. Optionally, the control device may comprise a parameter-setting unit and/or a determination unit for providing/determining control parameters for generating the additional gradient field. In particular, the determination unit may be configured to determine, for a predetermined direction, the control parameters defining an additional gradient pulse that causes the molecules of the paramagnetic contrast agent to move in the predetermined direction. Such determination can take place prior to each acquisition period used to acquire a partial data set of the dynamic data set.

Further functional units may likewise be provided for corresponding aspects of the method according to the disclosure. For example, a trigger unit may be provided for detecting the beginning and/or the end of a window of opportunity. Another option is an evaluation unit configured to derive, from partial data sets assigned to different predefined directions, information concerning isotropy of perfusion and/or diffusion in the target area, in particular in subvolumes, said information including, in particular, at least one parameter and/or at least one perfusion tensor, and/or a plurality of parameters of a multiparametric magnetic resonance measurement derived from the magnetic resonance data.

A computer program according to the disclosure can be loaded directly into a memory of a control device of a magnetic resonance device and comprises program instructions such that, when the computer program is executed on the control device, the latter is caused to carry out the steps of a method according to the disclosure. The computer program can be stored on an electronically readable data carrier according to the disclosure, which thus comprises, stored thereon, control information comprising at least one computer program according to the disclosure and which is designed such that, when the data carrier is used in a control device of a magnetic resonance device, the latter is configured to carry out the steps of a method according to the disclosure. The data carrier may in particular be a non-transient data carrier, for example a CD-ROM.

### BRIEF DESCRIPTION OF THE DRAWINGS

Further advantages and details of the present disclosure will emerge from the exemplary aspects described below and from the accompanying drawings, in which:

FIG. 1 shows a general flow chart of an exemplary aspect of the method according to the disclosure,

FIG. 2 schematically illustrates different types of contrast agent curves,

FIG. 3 shows a sequence of time periods as may be used in the method,

FIG. 4 shows a schematic diagram for the simultaneous acquisition of three slices following application of a movement force,

FIG. 5 shows a schematic diagram of data acquisition for determining a perfusion tensor,

FIG. 6 shows a schematic diagram of a magnetic resonance device according to the disclosure, and

FIG. 7 shows the functional structure of a control device for the magnetic resonance device.

### DETAILED DESCRIPTION

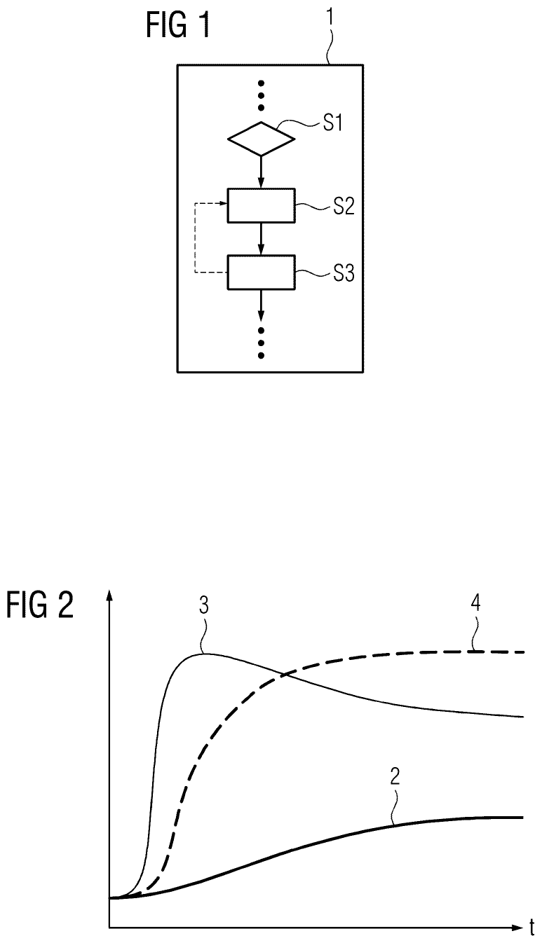

FIG. 1 shows a general flow chart of exemplary aspects of the method according to the disclosure. The steps shown are embedded in an examination process 1 of a multiparametric magnetic resonance measurement performed by a magnetic resonance device in accordance with a corresponding acquisition protocol. A magnetic resonance sequence, which in particular allows rapid data acquisition, preferably simultaneously in a plurality of slices, is used to acquire magnetic resonance data describing the perfusion and/or diffusion in a target area of a subject under examination, specifically with respect to subvolumes of the target area. The target area may be, for example, an organ, in particular a liver, prostate, or breast, and the examination process may be used for detection and/or staging of a cancer. During the examination process, prior to commencement of the method described here, the subject under examination is administered a magnetic resonance contrast agent, in this case a gadolinium-based contrast agent, which can accumulate in the interstitial spaces of the tissue of the target area.

In order to acquire magnetic resonance data relating to perfusion and/or diffusion from a dynamic data set, during an examination process 1, step S1 first involves monitoring to ascertain whether a window of opportunity is present. For this purpose, contrast agent curves acquired by a dynamic contrast-enhanced (DCE) measurement for subvolumes, here typically interstitial spaces in tissue of the target area to be examined, are evaluated to ascertain whether an opportunity condition is fulfilled.

FIG. 2 shows contrast agent curves (contrast agent concentration curves) of the type typically occurring when contrast agent molecules pass from blood vessels into the interstitial spaces. The contrast agent curve 2 of a first type shows a slow, progressive increase in contrast agent concentration in the interstitial space and is indicative of benign tissue. A contrast agent curve 3 of a third type shows an extremely rapid increase in contrast agent concentration up to a maximum, after which the contrast agent concentration begins to decrease (“wash-out”). This is indicative of the tissue being malignant. The contrast agent curve 4 of a second type lies between the first and third types and shows a fairly rapid increase with subsequent plateauing.

In the left half, all the contrast agent curves 2, 3, 4 show the initial passage of the contrast agent into the extracellular space by passive diffusion due to a concentration gradient. In the right half, however, significantly less dynamic behavior is observed as the concentration gradient progressively weakens. In the window of opportunity provided by an at least essentially constant contrast agent concentration in corresponding subvolumes, here interstitial spaces, a significant amount of influenceable contrast agent that is accessible to externally introduced dynamics is therefore present, so that the window of opportunity shall be utilized here to collect additional useful information about the tissue of the target area. The opportunity condition can, for example, check whether the maximum contrast agent concentration has been reached or exceeded and/or whether a change in the contrast agent concentration (for example, its temporal gradient) is below a threshold value while a contrast agent concentration exceeding a minimum concentration is present.

If the presence of a window of opportunity has been determined, then, in step S2, in at least one movement time period outside the magnetic resonance sequence, an additional gradient field is generated by means of additional gradient pulses that are output by actuation of a gradient coil arrangement of the magnetic resonance device, said additional gradient field exerting a movement force on the contrast agent molecules and thus introducing kinetic energy where contrast agent molecules are present, as described and explained above. In an acquisition period immediately following the movement time period, the magnetic resonance sequence is then used, in step S3, to acquire magnetic resonance data of the dynamic data set that describes the effects of the additional gradient field with regard to diffusion and/or perfusion.

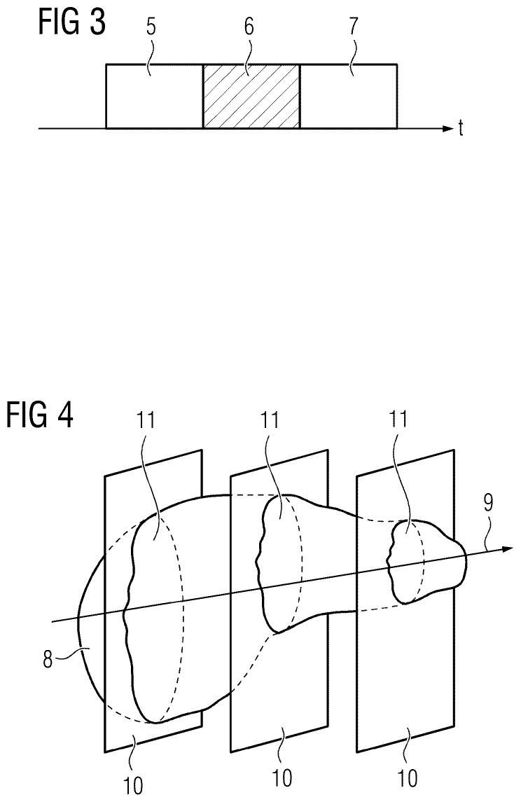

In general, it is expedient to provide at least one time sequence as shown in FIG. 3, in which, in a first acquisition period 5 before the additional gradient field is output, i.e. prior to step S2, magnetic resonance data of a reference data set is acquired with the magnetic resonance sequence, after which the additional gradient field is output in a movement time period 6. Immediately after the movement time period, a second acquisition period 7 follows, in which at least one partial data set of the dynamic data set is acquired using the magnetic resonance sequence. Such a sequence of time periods can be described as “scan”, “drive”, “scan again”, as already described above. By comparing the partial data set with the reference data set, effects of the additional gradient field can be observed. This sequence can also be continued, for example, by further movement time periods 6 with associated acquisition periods 7.

It should be noted that, similarly to step S1, the termination of the window of opportunity can also be monitored, for example by means of a termination condition, for example by checking whether the contrast agent concentration in the subvolumes falls below the minimum concentration and/or decreases too sharply. As also indicated in FIG. 1, additional gradient fields can be output repeatedly during the window of opportunity, and magnetic resonance data of the magnetic resonance data set can be acquired, i.e., steps S2 and S3 can be repeated, if necessary at least in part with acquisition of the reference data set prior to step S2. In particular, the sequence described in relation to FIG. 3 can be repeated multiple times.

This will first be described using some examples of DCE imaging directed to measuring the effect of contrast agent on relaxation time, in particular T1 or T2*. In each case, new dynamics for the distribution of the contrast agent in tissues are actively introduced when its own inherent passive dynamics (arising from differences in contrast agent concentration) are weak, with the window of opportunity being utilized for this purpose.

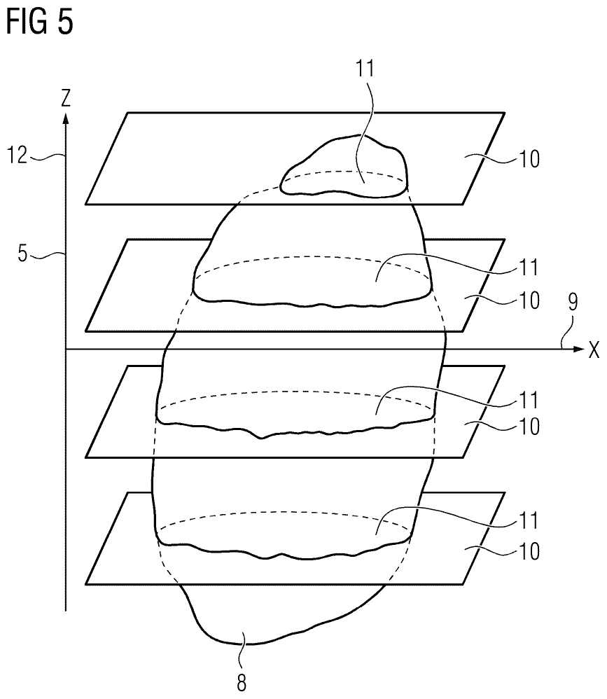

In a first specific exemplary aspect, between successive magnetic resonance scans (in acquisition periods 5 and 7), the contrast agent molecules are moved in a particular, predefined direction by a defined movement force. In other words, the kinetic energy is introduced in a directional manner by appropriately configuring the additional gradient field and, consequently, the additional gradient pulses that generate it. The magnetic resonance data of the dynamic data set acquired in the subsequent acquisition period 7 shows the result of this displacement of the contrast agent molecules and thus reveals new information about the tissue structure and the associated tissue permeability that restricts the free flow of contrast agent in the predefined direction. In this case, a plurality of slices are acquired simultaneously using an SMS technique in both the first acquisition period 5 and the second acquisition period 7, as also shown by way of example in FIG. 4.

The target area 8, for example, a target organ or tumor tissue, is shown schematically, together with the predefined direction 9. The plurality of parallel slices 10 are ordered successively along the predefined direction 9. Consequently, the driven and directed perfusion of the contrast agent through the target area 8 can be observed and evaluated in each target region 11, which can preferably take place automatically, but also visually by assessing the contrast enhancement or contrast reduction at different points in time during the sequence of movement time periods 6 and acquisition periods 5, 7.

In the acquisition periods 5, 7, T1-weighted magnetic resonance sequences can be used, in which the tissue permeability can be assessed by the T1 reduction due to a local accumulation of contrast agent at barriers. Similarly, it is also possible to use T2*-weighted magnetic resonance sequences in which local accumulations of contrast agent cause increased signal loss.

It should be noted that the increased probability of collisions between contrast agent molecules and water molecules also generally produces a stronger contrast until the kinetic energy introduced is dissipated accordingly, as explained above.

In further specific exemplary aspects, the isotropy or anisotropy of perfusion in the tissue may be assessed by repeatedly performing sequences of the type described for different predefined directions, thus allowing the perfusion in the different predefined directions to be compared. In other words, for example, using the “scan”, “drive”, “scan again” sequence of FIG. 3 and changing the predefined direction of the movement force by means of the additional gradient fields, a direction-related assessment can be made regarding the permeability for contrast agent molecules. For example, the predefined directions can correspond to Cartesian axes (X, Y, Z) and/or preferably be orthogonal to one another. For example, a first predefined direction can be a stand-out target area direction in which a strong deviation from other directions should be present, and a second predefined direction can be a direction for comparison. In the example of a breast, the glands, for example, may constitute such a stand-out direction that is known in advance.

In particular, in a third specific exemplary aspect, it is possible to determine a perfusion tensor. For this purpose, using the sequence according to FIG. 3, for example, a plurality of partial data sets of the dynamic data set are acquired for different combinations of two directions involved, namely the predefined direction in which the movement force acts and the direction in which the displacement of the contrast agent, i.e. the perfusion, is observed (specifically the slice direction). FIG. 5 shows, by way of example, how data can be acquired for an off-diagonal component of the perfusion tensor (here, the ZX or XZ component). The movement force is applied in the predefined direction 9, in this case, along the X axis. The slices 10 of the SMS measurement are ordered successively, in this case relatively close together, in a slice direction 12, here along the Z axis, in which the motion pattern resulting from application of the movement force is observed. A plurality of parallel slices 10 are thus acquired simultaneously at different slice positions along the Z axis. This allows the perfusion of the contrast agent through the target area 8 to be assessed in each target region 11. Calculation methods such as those known from diffusion tensor imaging (DTI) can be used to determine the perfusion tensor from six or more such measurements of partial data sets.

Since the introduction of kinetic energy and collisions with water molecules can also actively drive general diffusion, diffusion-weighted imaging (DWI) can also be improved in other exemplary aspects using the approach proposed here, by actively moving contrast agent molecules by means of the additional gradient field.

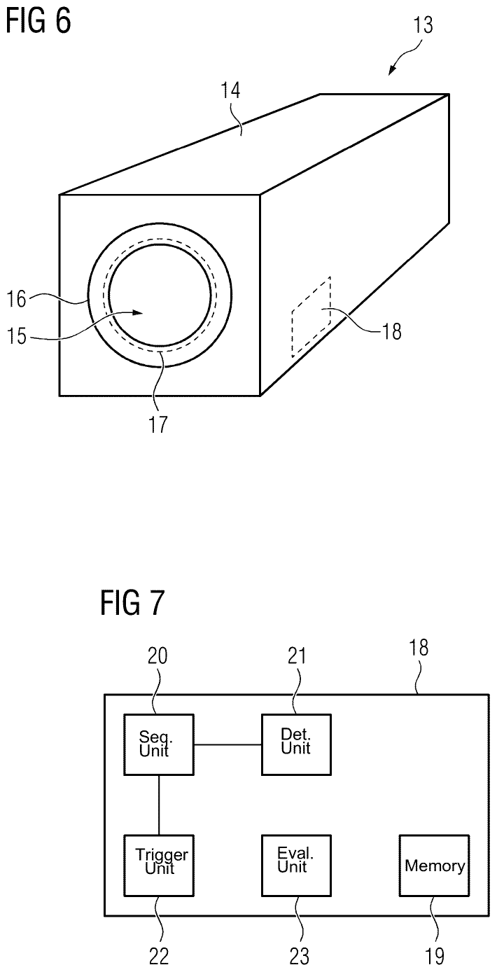

FIG. 6 shows a schematic diagram of a magnetic resonance device 13 according to the disclosure. As is generally known, this device has a main magnet unit 14 containing the main magnet, in particular a superconducting main magnet, which generates the main magnetic field (B0 field). Located in the main magnet unit 14 is a cylindrical patient bore 15 into which a subject under examination can be moved on a patient table (not shown in detail) in order to acquire magnetic resonance data. Surrounding the patient bore 15 are a gradient coil arrangement 16 and a radiofrequency coil arrangement 17. Local coil arrangements can of course also be used as the radiofrequency coil arrangement or as part thereof. Operation of the magnetic resonance device 13 is controlled by a control device 18. The latter is designed to carry out the method according to the disclosure.

FIG. 7 shows the functional structure of the control device 18 in more detail. In addition to a memory 19, the control device 18 has, as a further functional unit, a sequence unit 20 which controls the acquisition operation of the magnetic resonance device 13 and is therefore designed in particular to acquire magnetic resonance data using the magnetic resonance sequence, for example, in step S3, i.e., in the acquisition periods 5, 7. In the present case, the sequence unit 20 is also designed to control the gradient coil arrangement 16 to output additional gradient pulses for generating the additional gradient field (step S2). Corresponding additional gradient pulses assigned, for example, to predefined directions can optionally be provided by a parameter-setting unit and/or a determination unit 21.

The control device 18 may also comprise a trigger unit 22 that checks, in accordance with step S1, whether the window of opportunity has been reached. The trigger unit 22 may also check whether the window of opportunity has ended.

In an evaluation unit 23, evaluations of magnetic resonance data, for example, also of the magnetic resonance data of the dynamic data set (in particular together with associated reference data), can be performed. For example, the evaluation unit 23 can be designed to determine a perfusion tensor from corresponding partial data sets (and possibly reference data sets) that are assigned to different predefined directions and possibly combinations of slice directions and predefined directions. With regard to the other exemplary aspects shown, the effects of the additional gradient field can likewise be determined or quantified by evaluation, in particular in order to obtain further useful information about the distribution and properties of the tissue in the target area.

Independent of the grammatical term usage, individuals with male, female, or other gender identities are included within the term.

1. A computer-implemented method for operating a magnetic resonance device, the method comprising:
acquiring, as part of an examination process, magnetic resonance data describing diffusion and/or perfusion in a target area of a subject under examination in which an exogenous paramagnetic contrast agent is present, using a magnetic resonance sequence; and
prior to at least one acquisition period in which magnetic resonance data of a dynamic data set is acquired using the magnetic resonance sequence, outputting an additional magnetic gradient field to generate a magnetic movement force that acts on the contrast agent to introduce kinetic energy into the target area, wherein the additional magnetic gradient field is output separately from pulses of the magnetic resonance sequence.

2. The method of claim 1, wherein the additional gradient field is output during a dedicated movement time period that precedes the acquisition period and is temporally separated from the pulses of the magnetic resonance sequence, or is output in parallel with at least some of the pulses of the magnetic resonance sequence.

3. The method of claim 1, wherein the additional gradient field is generated by additional gradient pulses applied by a gradient coil arrangement of the magnetic resonance device.

4. The method of claim 1, wherein the output of the additional gradient field and the subsequent acquisition occur within a window of opportunity of the examination process in which an at least substantially constant contrast agent concentration is present in a subvolume of interest, which is an interstitial space, bounded by at least one anatomical structure of the target area.

5. The method of claim 4, wherein the window of opportunity comprises a period following an inflow phase of the contrast agent, during which the contrast agent accumulates in the subvolume, and/or wherein a presence of the window of opportunity is determined from a temporal contrast agent curve of at least one voxel of the subvolume, the voxel being obtained from a previously acquired portion of the magnetic resonance data.

6. The method of claim 1, wherein the magnetic resonance data of the dynamic data set is acquired at least in part using a simultaneous multi-slice acquisition technique in at least three slices.

7. The method of claim 1, wherein the additional gradient field causes movement of molecules of the paramagnetic contrast agent in a predefined direction.

8. The method of claim 7, wherein the magnetic resonance data of the dynamic data set is acquired as a contrast-enhanced measurement with T1 contrast and/or T2* contrast.

9. The method of claim 8, wherein different partial data sets of the dynamic data set are acquired in acquisition periods following the output of different additional gradient fields that induce movement in different predefined directions, and are evaluated with respect to isotropy of perfusion and/or diffusion.

10. The method of claim 7, wherein, in order to measure a perfusion tensor in a measurement sequence, partial data sets of the dynamic data set are acquired and evaluated for different predefined directions of movement induced by the additional gradient field.

11. The method of claim 1, wherein, for diffusion-weighted acquisition of the dynamic data set, the additional gradient field is output to increase diffusion motion.

12. The method of claim 1, wherein the dynamic data set is acquired as part of a multiparametric magnetic resonance measurement, and the dynamic data set is used to determine at least one parameter of a plurality of parameters to be determined in the multiparametric measurement.

13. A magnetic resonance device, comprising a control device designed to carry out the method of claim 1.

14. A non-transitory electronically readable data carrier having stored there a computer program which, when executed by a control device of a magnetic resonance device, causes the control device to carry out the method of claim 1.
